(19) United States
(12) Patent Application Publication
(10) Pub. No.: US 2026/0161869 A1
(43) Pub. Date: Jun. 11, 2026

(54) REPLACEMENT OF NAME FOR LOCAL SIGNALS WITH GLOBAL NAME IN RTL CODE BLOCKS

(71) Applicant: Singularity Dynamics Private Limited, Bangalore (IN)

(72) Inventor: Harish Kumar, Bangalore (IN)

(21) Appl. No.: 19/416,109

(22) Filed: Dec. 11, 2025

Related U.S. Application Data
(60) Provisional application No. 63/730,479, filed on Dec. 11, 2024.

(51) Int. Cl. G06F 30/33; G06F 30/31; G06F 30/327

(52) U.S. Cl. CPC G06F 30/33; G06F 30/31; G06F 30/327

(57) ABSTRACT

Disclosed subject matter relates to verification and debugging tool and method for replacing of names of local signal with the global name in Register Transfer Language (RTL) code blocks. Verification and debugging tool receives RTL code in Hardware Description Language (HDL). Further, verification and debugging tool parses RTL code, and generate abstract syntax tree representing syntactic structure of RTL code. Thereafter, converts abstract syntax tree into RTL directed graph. Furthermore, determines one or more unique global names for signals across overall hierarchy of RTL blocks, and replace local signal names in lower-level RTL blocks with corresponding global names from higher-level RTL blocks without displaying full hierarchy preceding global name. Finally, displays RTL directed graph with directional links indicating signal flow, and further configured to provide interactive mechanisms to display at least one of: full hierarchy of RTL blocks preceding global name, and replaced local name associated with global name.

### CROSS-REFERENCE TO RELATED APPLICATIONS

The present application claims the benefit of priority to U.S. Provisional Application No. 63/730,479, filed on Dec. 11, 2024; the contents of which are hereby incorporated by reference herein in their entirety.

### TECHNICAL FIELD

The present disclosure relates to electronic design. Particularly, the present disclosure relates to replacing of names of local signal with the global name in Register Transfer Language (RTL) code blocks.

### BACKGROUND

Modern electronic design is typically performed with Computer-Aided Design (CAD) tools or Electronic Design Automation (EDA) systems. To design an Integrated Circuit (IC) device, a designer first creates high-level behavior descriptions of the IC device using a Hardware Description Language (HDL) such as Verilog and VHSIC Hardware Description Language (VHDL). As the complexity of IC devices is growing exponentially due to changes such as shrinking in size of the IC chips and integration of more functionalities onto a single IC chip, the behavior descriptions of the devices are also becoming complex and contain a large number of code blocks written in HDL for the IC chips.

There may be errors or problems in the written code blocks, which may be identified and resolved using verification and debugging tools. The existing verification and debugging tools represent different RTL code blocks. When, within an Overall hierarchy of RTL blocks, lower-level RTL blocks are instantiated within higher-level RTL blocks. In such instances, a same signal may be assigned different names in the higher-level RTL blocks and the lower-level RTL blocks, creating a challenge during verification and debugging process performed over different RTL code blocks. Specifically, the need to track signal name changes across hierarchical levels complicates the process. This issue is further exacerbated when the same lower-level block is instantiated multiple times across multiple hierarchical levels. In such cases, while the signals shared between the higher-level RTL blocks and the lower-level RTL blocks in the overall hierarchy of RTL blocks will have distinct names at the higher level, the signals will retain identical local names within each instantiation of the lower-level block. This makes the process of verification and debugging very complex, time-consuming and inefficient.

Therefore, there is a need for a verification and debugging tool that can replace the local signal names with the global signal name in the RTL code blocks.

The information disclosed in this background of the disclosure section is only for enhancement of understanding of the general background of the invention and should not be taken as an acknowledgement or any form of suggestion that this information forms the prior art already known to a person skilled in the art.

### SUMMARY

Disclosed herein is a verification and debugging tool for Register Transfer Level (RTL) code. The verification and debugging tool comprises an input interface configured to receive RTL code in a Hardware Description Language (HDL). Further, the verification and debugging tool comprises an RTL parser configured to parse the RTL code, and generate an abstract syntax tree representing the syntactic structure of the RTL code. Thereafter, the verification and debugging tool comprises a graph converter adapted to convert the abstract syntax tree into an RTL directed graph. The RTL directed graph comprises a plurality of RTL code blocks represented as nodes and each node corresponding to a functional block of the RTL code. Furthermore, the verification and debugging tool comprises a replacement module configured to determine one or more unique global names for signals across an overall hierarchy of RTL blocks, and replace local signal names in lower-level RTL blocks with corresponding global names from higher-level RTL blocks without displaying full hierarchy preceding global name. Finally, the verification and debugging tool comprises a visual display configured to display the RTL directed graph with directional links indicating signal flow, and further configured to provide interactive mechanisms to display at least one of: the full hierarchy of RTL blocks preceding the global name, and the replaced local name associated with the global name.

Further, disclosed herein is a method of replacing of names of local signal with the global name in Register Transfer Language (RTL) code blocks. The method includes receiving RTL code in a Hardware Description Language (HDL). Further, the method includes parsing the RTL code, and generating an abstract syntax tree representing the syntactic structure of the RTL code. Thereafter, the method includes converting the abstract syntax tree into an RTL directed graph. The RTL directed graph comprises a plurality of RTL code blocks represented as nodes and each node corresponding to a functional block of the RTL code. Furthermore, the method includes determining one or more unique global names for signals across an overall hierarchy of RTL blocks. Thereafter, the method includes replacing local signal names in lower-level RTL blocks with corresponding global names from higher-level RTL blocks without displaying full hierarchy preceding global name. Finally, the method includes displaying the RTL directed graph with directional links indicating signal flow, and to providing interactive mechanisms to display at least one of: the full hierarchy of RTL blocks preceding the global name, and the replaced local name associated with the global name.

Furthermore, the present disclosure relates to a non-transitory computer readable medium including instructions stored thereon that when processed by at least one processor, cause a verification and debugging tool to perform operations comprising receiving RTL code in a Hardware Description Language (HDL). Further, the instructions cause the processor to parse the RTL code, and generate an abstract syntax tree representing the syntactic structure of the RTL code. Thereafter, the instructions cause the processor to convert the abstract syntax tree into an RTL directed graph. The RTL directed graph comprises a plurality of RTL code blocks represented as nodes and each node corresponding to a functional block of the RTL code. Furthermore, the instructions cause the processor to determine one or more unique global names for signals across an overall hierarchy of RTL blocks, and replace local signal names in lower-level RTL blocks with corresponding global names from higher-level RTL blocks without displaying full hierarchy preceding global name. Finally, the instructions cause the processor to display the RTL directed graph with directional links indicating signal flow, and provide interactive mechanisms to display at least one of: the full hierarchy of RTL blocks preceding the global name, and the replaced local name associated with the global name.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE ACCOMPANYING DRAWINGS

The accompanying drawings, which are incorporated in and constitute a part of this disclosure, illustrate exemplary embodiments and, together with the description, explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and regarding the accompanying figures, in which:

FIG. 1 shows an exemplary environment of replacing of names of local signal with the global name in Register Transfer Language (RTL) code blocks, in accordance with some embodiments of the present disclosure;

FIG. 2 shows an exemplary illustration of the replacement of the local name in the signal with the global name in the overall hierarchy of RTL blocks, in accordance with an embodiment of the present disclosure;

FIG. 3 shows a flowchart illustrating method of replacing of names of local signal with the global name in Register Transfer Language (RTL) code blocks, in accordance with some embodiments of the present disclosure; and

FIG. 4 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood that it is not intended to limit the disclosure to the specific forms disclosed, but on the contrary, the disclosure is to cover all modifications, equivalents, and alternative falling within the scope of the disclosure.

The terms “comprises”, “comprising”, “includes”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or identity server proceeded by “comprises . . . a” does not, without more constraints, preclude the existence of other elements or additional elements in the system or method.

The terms like “at least one” and “one or more” may be used interchangeably throughout the description.

The terms like “verification and debugging tool”, “verification tool”, “debugging tool” and “tool” may be used interchangeably throughout the description.

The terms like “RTL code” and “code” may be used interchangeably throughout the description.

The terms like “circuit designer” and “designer” may be used interchangeably throughout the description.

The present disclosure relates to a verification and debugging tool that represents the Register Transfer Level (RTL) code blocks. The RTL code is a coding style used in digital system design and computer engineering, that is written using Hardware Description Language (HDL) like Verilog or VHDL. The RTL code defines the functioning of a digital circuit that may include multiple code blocks. In particular, RTL describes how the data transforms and flows from one register to another. The transformation of data is performed by combinational logic that exists between the registers. The operation of the RTL code is verified by using the verification tool and if any errors or problems arise in the code during its operation, verification engineer may use debugging tool to resolve the problems. The tool may convert the RTL code into an abstract syntax tree and then convert the abstract syntax tree into an RTL directed graph. The present disclosure describes the tool which provides the global visual view of all the code blocks of the RTL code in the form of the directed graph.

In the embodiment, the tool disclosed in the present disclosure provides a provision where one or more unique global names present in higher-level RTL blocks are driven down the overall hierarchy of RTL blocks. Local names present in lower-level RTL blocks may be replaced directly by the one or more corresponding unique global names.

In the present disclosure, the verification and debugging tool provides a mechanism to display full hierarchy of RTL block preceding the global name in a local signal where the local name is replaced by the global name. Such display of the full hierarchy of the RTL block preceding the global name is provided when hovering over or clicking a specific sensitive region around the local signal. Further, a mechanism to display the local names which have been replaced is also provided if needed by hovering over or clicking a specific sensitive region around the local signal.

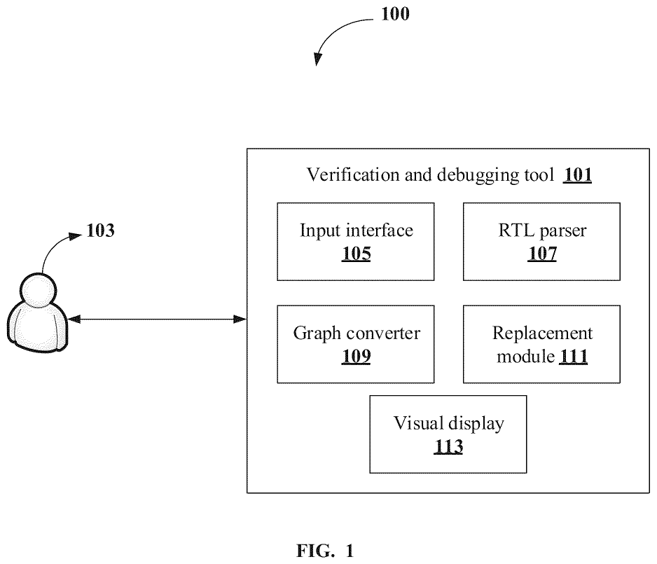

FIG. 1 shows an exemplary environment of replacing of names of local signal with the global name in Register Transfer Language (RTL) code blocks, in accordance with some embodiments of the present disclosure.

Exemplary environment 100 includes a verification and debugging tool 101 and a user 103. The verification and debugging tool 101 may include an input interface 105, an RTL parser 107, a graph converter 109, a replacement module 111 and a visual display 113. The user 103 may interact with the verification and debugging tool 101 using the input interface 105 and the visual display 113. The input interface 105 may include, without limitation, keyboards, mouse, touchscreens, and the like, which allow direct user interaction. The input interface 105 may also receive input from any sources provided by the user 103. As an example, the input interface 105 may receive input from Uniform Resource Locator (URL). The output may be displayed on the visual display 113. As an example, the visual display 113 may include, without limitation, an electronic screen, a touchscreen and the like, which allows display of the output. In an embodiment, the verification and debugging tool 101 may be a computing device. As an example, the computing device may be any device used by the user 103 such as, but not limited to, mobile phones, smartphones, laptops, and Personal Computers (PCs). In some embodiments, the verification and debugging tool 101 may be configured within the computing device (not shown in figure).

In an embodiment, the input interface 105 may be configured to receive RTL code in a Hardware Description Language (HDL) from the user 103. The HDLs may include, without limitation, at least one of Verilog and VHSIC Hardware Description Language (VHDL). As an example, the user 103 may be a circuit designer. The RTL code may describe behavior and component connections of a circuit such as an Integrated Circuit (IC). The RTL code may include one or more code blocks describing the operations of one or more entities/components of the circuit. In an embodiment, the input interface 105 may be further configured to validate syntax of the RTL code. If syntax error is detected, the syntax error may be displayed on the visual display 113 allowing the user 103 to edit the RTL code to rectify the syntax error. The input interface 105 may also detect any error which may affect execution of the RTL code.

In an embodiment, upon receiving the RTL code, the RTL parser 107 may be configured to parse the RTL code. In an embodiment, the RTL parser 107 may parse the RTL code by performing lexical and syntactic analysis to identify structural elements such as modules, signals, assignments, and control statements. Based on this analysis, the RTL parser 107 may generate an Abstract Syntax Tree (AST) that represents the hierarchical syntactic structure of the RTL code. The AST may include nodes corresponding to language constructs and captures parent-child relationships between statements, thereby providing a structured and unambiguous representation of the RTL code for subsequent transformation into an RTL directed graph.

In an embodiment, upon generating the AST, the graph converter 109 may be configured to convert the AST into the RTL directed graph. The RTL directed graph may include a plurality of RTL code blocks represented as nodes and each node corresponding to a functional block of the RTL code. The graph converter 109 may be further configured to represent signals of the RTL code as vertices of the RTL directed graph. The graph converter 109 may also provide one or more customizable display options for the RTL directed graph. The customizable options may enable the user 103 to modify the visual representation of the RTL directed graph to suit specific debugging or analysis requirements. The one or more customizable display options may include, without limitation, color coding for different signal types or logic states, adjustable node sizes to emphasize critical modules, selectable layers for viewing control flow or data flow independently, and variable line thickness or styles to indicate signal width or type. Additional customization may include zoom functionality for detailed inspection of individual nodes, dynamic visual effects to represent changes in signal values over time, and grouping of related nodes into functional sections. These customizable display options enhance clarity, improve navigation within complex RTL designs, and facilitate efficient identification of design issues during verification and debugging. In some embodiments, the RTL directed graph may be configured to display at least one of control flow and data flow. At least one of the control flow and the data flow may be displayed in a visually distinguishable manner. The visual distinction between the control flow and the data flow may be obtained using one of different arrow styles or different colors. In other words, the visual distinction between control flow and data flow within the RTL directed graph is achieved through the use of differentiated graphical indicators. In one embodiment, the distinction is provided by employing different arrow styles, such as solid arrows for data flow and dashed arrows for control flow, or by varying arrowhead shapes to represent signal types. Alternatively, the distinction may be implemented using different colors for the respective flows, enabling clear and intuitive identification of control signals versus data paths. These visual differentiation techniques enhance the readability of complex RTL designs and facilitate efficient debugging and verification by allowing users to quickly interpret the nature of each connection within the graph.

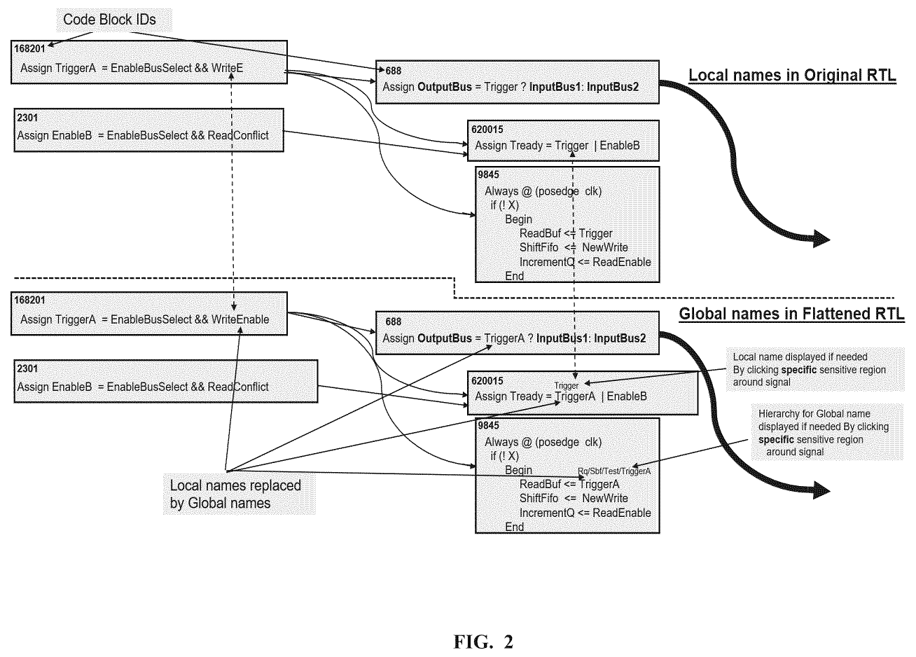

In an embodiment, upon converting the AST into the RTL directed graph, the replacement module 111 may be configured to determine one or more unique global names for signals across an overall hierarchy of RTL blocks. Further, the replacement module 111 may be configured to replace local signal names in lower-level RTL blocks with corresponding global names from higher-level RTL blocks without displaying full hierarchy preceding global name. The overall hierarchy of RTL blocks may be flattened by driving global names from higher level RTL blocks down through lower level RTL blocks. The replacement module 111 may be configured to verify uniqueness in name of each signal name across the overall hierarchy of RTL blocks. The verification and debugging tool may include a memory (not shown in figure) configured to store node block structures and signal mappings, including replaced local names and corresponding global names. Further, the memory may store mappings between the local signal names in lower level RTL blocks and corresponding global names from higher level RTL blocks to support interactive display of replaced local names. Exemplary illustrations are provided in FIGS. 2A and 2B.

In an embodiment, upon storing the node block structures, the visual display 113 may be configured to display the RTL directed graph with directional links indicating signal flow, and the visual display 113 may be further configured to provide interactive mechanisms to display at least one of: the full hierarchy of RTL blocks preceding the global name, and the replaced local name associated with the global name. The visual display 113 may provide an interactive mechanism which may include, without limitation, at least one of hovering over or clicking a sensitive region around a displayed global name to display the full hierarchy or the replaced local name. The visual display 113 may also include an output interface configured to display debug information related to RTL code analysis and results (not shown in figure). In some embodiments, the visual display 113 and the output interface may be same. The visual display 113 and the output interface may also display results in a graphical format. In an embodiment, the visual display 113 may be configured to support zoom functionality for viewing details of individual code blocks or nodes. The zoom functionality may allow the user 103 to focus on specific areas of the RTL directed graph while preserving the ability to return to an overall view. The visual display 113 may also include user interface which may allow the user interactions within the visual display 113. The user interface may allow the user 103 to group multiple code blocks into functional sections. The visual display 113 provides an integrated environment for real-time analysis and debugging of RTL designs. By replacing the local signal names in lower-level RTL blocks with corresponding global names from higher-level RTL blocks without displaying full hierarchy preceding global name, the verification and debugging tool 101 enhances interpretability of RTL graphs and reduces ambiguity during debugging. This capability enables engineers to track signal name changes across hierarchical levels. As a result, verification workflows become more efficient, accelerating error localization and minimizing the time required to identify and resolve functional issues.

FIG. 2 shows an exemplary illustration of the replacement of the local name in the signal with the global name in the overall hierarchy of RTL blocks, in accordance with an embodiment of the present disclosure. FIG. 2 shows a comparison between local names in original RTL and the global names provided in the overall hierarchy of the flattened RTL blocks.

In the exemplary embodiment provided in FIG. 2, a unique identifier of a code block may be known as a code block identity (ID) is assigned to each RTL code block. In the original RTL, for the code block id ‘168201’ a global name of the signal is assigned as ‘TriggerA’. In another RTL code block having a code block id of ‘688’ is using the signal/output of ‘168201’ but the code block id of ‘688’ is using a local name of ‘Trigger’ in the signal of RTL code block. Similarly, the code block id of ‘620015’ is also using the output of ‘168201’ but again using the local name ‘Trigger’ in the RTL code block.

In the exemplary embodiment, there may be multiple RTL code blocks using the output of ‘168201’, however, all such RTL code blocks are using the different local names for the signal/output of ‘168201’ in their respective code blocks. When using such different local names in multiple code blocks then a challenge is imposed if one or more bugs are found during verification and debugging process performed over those RTL code blocks. For example, a challenge can be identified as pinpointing the source of error or even if the error is detected then backtracking to the original source can be very complex, time-consuming and inefficient.

In the exemplary embodiment of FIG. 2, in the scenario where the global names are provided in the overall hierarchy of the flattened RTL blocks for the corresponding local names, the process of verification and debugging becomes faster, easier and more efficient. Now for the code block id ‘168201’ a global name of the signal is assigned as ‘TriggerA’. In another RTL code block having code block id of ‘688’ is using the signal/output of ‘168201’ and now the code block id of ‘688’ is using a global name instead of local name i.e., ‘TriggerA’ instead of local name “Trigger” in the RTL code block. Similarly, the code block id of ‘620015’ is also using the output of ‘168201’ where the global name of ‘TriggerA’ has been used in the RTL code block. The benefit of using the global name is that the readability of the overall hierarchy of RTL blocks is improved, due to which the tracking of the source of the error becomes quick.

In the exemplary embodiment of FIG. 2, when the local names in lower-level RTL blocks are replaced with the corresponding global name, then the local signal as such is not replaced. As can be seen in an example, when a user hovers over or click a specific sensitive region around the global name ‘TriggerA’ if there is any local signal associated with the global signal, then the local name of that RTL code block may be displayed.

In another example, when the user hovers over or click a specific sensitive region around the global name ‘TriggerA’ in the local signal having the code block id of ‘9845’, then the full hierarchy of RTL block preceding the global name may be displayed in the local signal.

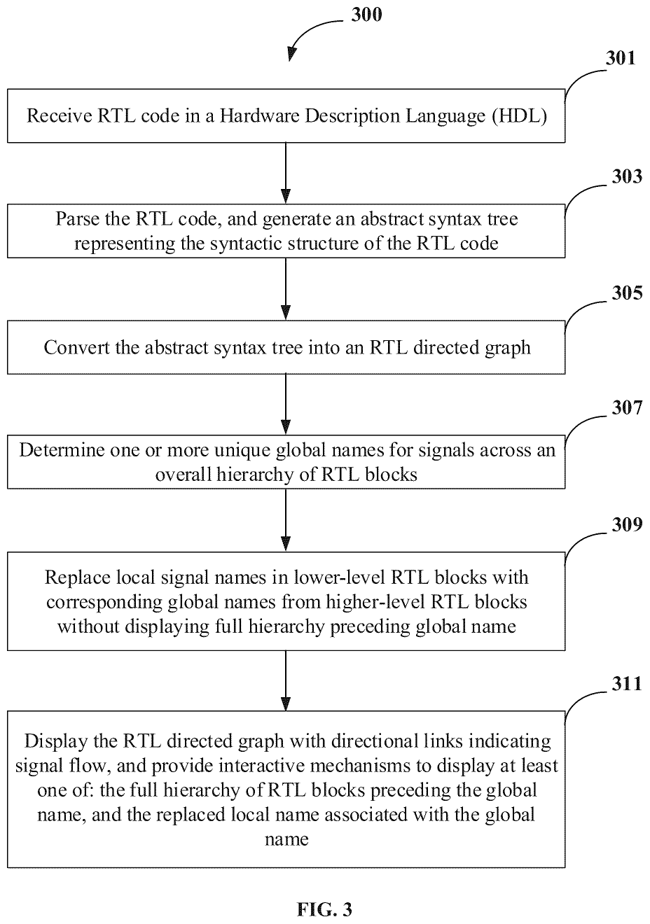

FIG. 3 is a flowchart illustrating a method of replacing of names of local signal with the global name in Register Transfer Language (RTL) code blocks, in accordance with some embodiments of the present disclosure.

As illustrated in FIG. 3, the method 300 may include one or more blocks illustrating a method of replacing of names of local signal with the global name in Register Transfer Language (RTL) code blocks, using the verification and debugging tool 101 illustrated in FIG. 1. The method 300 may be described in the general context of computer executable instructions. Generally, computer executable instructions can include routines, programs, objects, components, data structures, procedures, modules, and functions, which perform specific functions or implement specific abstract data types.

The order in which the method 300 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At block 301, the method 300 includes receiving, by a processor of the verification and debugging tool 101, RTL code in a Hardware Description Language (HDL). The HDLs may include at least one of Verilog and VHSIC Hardware Description Language (VHDL). Further, the processor may validate syntax of the RTL code.

At block 303, the method 300 includes parsing, by the processor, the RTL code, and generating an abstract syntax tree representing the syntactic structure of the RTL code.

At block 305, the method 300 includes converting, by the processor, the abstract syntax tree into an RTL directed graph. The RTL directed graph may include a plurality of RTL code blocks represented as nodes and each node corresponding to a functional block of the RTL code. The processor may represent signals as vertices and flylines to indicate fan-in and fan-out connections between RTL code blocks. Further, the processor may provide one or more customizable display options for the RTL directed graph. The processor may support zoom functionality for viewing details of individual code blocks or nodes. The zoom functionality may allow a user 103 to focus on specific areas of the RTL directed graph while preserving ability to return to an overall view. The RTL directed graph may be configured to display least one of control flow and data flow, wherein the at least one of the control flow and the data flow is displayed in a visually distinguishable manner.

At block 307, the method 300 includes determining, by the processor, one or more unique global names for signals across an overall hierarchy of RTL blocks. The overall hierarchy of RTL blocks may be flattened by driving global names from higher-level RTL blocks down through lower-level RTL blocks.

At block 309, the method 300 includes replacing, by the processor, local signal names in lower-level RTL blocks with corresponding global names from higher-level RTL blocks without displaying full hierarchy preceding global name. The processor may be configured to verify uniqueness in name of each signal name across the overall hierarchy of RTL blocks. Further, the processor may maintain the full hierarchy of RTL blocks preceding the global name while visually displaying only the global name in the local signal names. The node block structures and signal mappings, including replaced local names and corresponding global names may be stored in a memory. Further, mappings between the local signal names in lower level RTL blocks and corresponding global names from higher level RTL blocks may also be stored in the memory to support interactive display of replaced local names.

At block 311, the method 300 includes displaying, by the processor, the RTL directed graph with directional links indicating signal flow, and provide interactive mechanisms to display at least one of: the full hierarchy of RTL blocks preceding the global name, and the replaced local name associated with the global name. The processor may configure the visual display 113 to provide an interactive mechanism. The interactive mechanism may include, without limitation, at least one of hovering over or clicking a sensitive region around a displayed global name to display the full hierarchy or the replaced local name. The processor may configure the visual display 113 to support zoom functionality for viewing details of individual code blocks or nodes. The zoom functionality may allow the user 103 to focus on specific areas of the RTL directed graph while preserving the ability to return to an overall view.

### Computer System

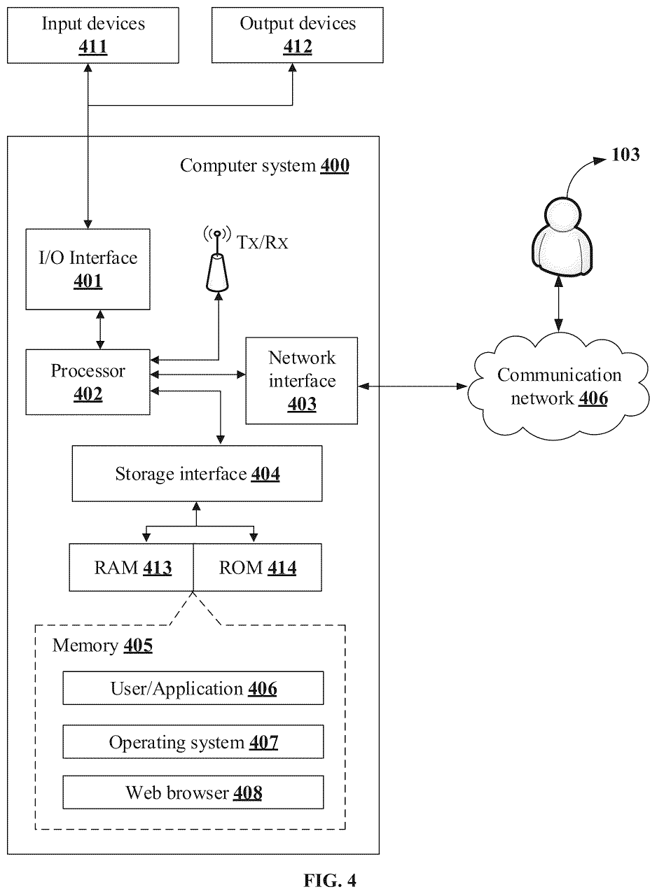

FIG. 4 illustrates a block diagram of an exemplary computer system 400 for implementing embodiments consistent with the present disclosure. In an embodiment, the computer system 400 may be a verification and debugging tool 101 illustrated in FIG. 1. The computer system 400 may include a central processing unit (“CPU” or “processor” or “memory controller”) 402. The processor 402 may comprise at least one data processor for executing program components for executing user- or system-generated business processes. A user may include a network manager, an application developer, a programmer, an organization, or any system/sub-system being operated parallelly to the computer system 400. The processor 402 may include specialized processing units such as integrated system (bus) controllers, memory controllers/memory management control units, floating point units, graphics processing units, digital signal processing units, etc.

The processor 402 may be disposed in communication with one or more Input/Output (I/O) devices (411 and 412) via I/O interface 401. The I/O interface 401 may employ communication protocols/methods such as, without limitation, audio, analog, digital, stereo, IEEER-1394, serial bus, Universal Serial Bus (USB), infrared, PS/2, BNC, coaxial, component, composite, Digital Visual Interface (DVI), high-definition multimedia interface (HDMI), Radio Frequency (RF) antennas, S-Video, Video Graphics Array (VGA), IEEE 802.n/b/g/n/x, Bluetooth, cellular (e.g., Code-Division Multiple Access (CDMA), High-Speed Packet Access (HSPA+), Global System For Mobile Communications (GSM), Long-Term Evolution (LTE) or the like), etc. Using the I/O interface 401, the computer system 400 may communicate with one or more I/O devices 411 and 412.

In some embodiments, the processor 402 may be disposed in communication with a network 409 via a network interface 403. The network interface 403 may communicate with the network 409. The network interface 403 may employ connection protocols including, without limitation, direct connect, Ethernet (e.g., twisted pair 10/100/1000 Base T), Transmission Control Protocol/Internet Protocol (TCP/IP), token ring, IEEE 802.11a/b/g/n/x, etc.

In an implementation, the preferred network 409 may be implemented as one of the several types of networks, such as intranet or Local Area Network (LAN) and such within the organization. The preferred network 409 may either be a dedicated network or a shared network, which represents an association of several types of networks that use a variety of protocols, for example, Hypertext Transfer Protocol (HTTP), Transmission Control Protocol/Internet Protocol (TCP/IP), Wireless Application Protocol (WAP) etc., to communicate with each other. Further, the network 409 may include a variety of network devices, including routers, bridges, RAN nodes, computing devices, storage devices, etc. Using the network interface 403 and the network 409, the computer system 400 may communicate with a user 103.

In some embodiments, the processor 402 may be disposed in communication with a memory 405 (e.g., RAM 413, ROM 414, etc. as shown in FIG. 6) via a storage interface 404. The storage interface 404 may connect to memory 405 including, without limitation, memory drives, removable disc drives, etc., employing connection protocols such as Serial Advanced Technology Attachment (SATA), Integrated Drive Electronics (IDE), IEEE-1394, Universal Serial Bus (USB), fiber channel, Small Computer Systems Interface (SCSI), etc. The memory drives may further include a drum, magnetic disc drive, magneto-optical drive, optical drive, Redundant Array of Independent Discs (RAID), solid-state memory devices, solid-state drives, etc.

The memory 405 may store a collection of program or database components, including, without limitation, user/application interface 406, an operating system 407, a web browser 408, and the like. In some embodiments, computer system 400 may store user/application data 406, such as the data, variables, records, etc. as described in this invention. Such databases may be implemented as fault-tolerant, relational, scalable, secure databases such as Oracle® or Sybase®.

The operating system 407 may facilitate resource management and operation of the computer system 400. Examples of operating systems include, without limitation, APPLE® MACINTOSH® OS X®, UNIX®, UNIX-like system distributions (E.G., BERKELEY SOFTWARE DISTRIBUTION® (BSD), FREEBSD®, NETBSD®, OPENBSD, etc.), LINUX® DISTRIBUTIONS (E.G., RED HAT®, UBUNTU®, KUBUNTU®, etc.), IBMx OS/2®, MICROSOFT® WINDOWS® (XP®, VISTA®/7/8, 10 etc.), APPLE IOS®, GOOGLE™ ANDROID™, BLACKBERRY® OS, or the like.

The user interface 406 may facilitate display, execution, interaction, manipulation, or operation of program components through textual or graphical facilities. For example, the user interface 406 may provide computer interaction interface elements on a display system operatively connected to the computer system 400, such as cursors, icons, check boxes, menus, scrollers, windows, widgets, and the like. Further, Graphical User Interfaces (GUIs) may be employed, including, without limitation, APPLE MACINTOSH® operating systems' Aqua®, IBM® OS/2®, MICROSOFT WINDOWS® (e.g., Aero, Metro, etc.), web interface libraries (e.g., ActiveX®, JAVA®, JAVASCRIPT®, AJAX, HTML, ADOBE® FLASH®, etc.), or the like.

The web browser 408 may be a hypertext viewing application. Secure web browsing may be provided using Secure Hypertext Transport Protocol (HTTPS), Secure Sockets Layer (SSL), Transport Layer Security (TLS), and the like. The web browsers 408 may utilize facilities such as AJAX, DHTML, ADOBE FLASH®, JAVASCRIPT®, JAVA®, Application Programming Interfaces (APIs), and the like. Further, the computer system 400 may implement a mail RAN node stored program component. The mail RAN node may utilize facilities such as ASP, ACTIVEX®, ANSI® C++/C #, MICROSOFT®, .NET, CGI SCRIPTS, JAVA®, JAVASCRIPT®, PERL®, PHP, PYTHON®, WEBOBJECTS®, etc. The mail RAN node may utilize communication protocols such as Internet Message Access Protocol (IMAP), Messaging Application Programming Interface (MAPI), MICROSOFT exchange, Post Office Protocol (POP), Simple Mail Transfer Protocol (SMTP), or the like. In some embodiments, the computer system 400 may implement a mail client stored program component. The mail client may be a mail viewing application, such as APPLE® MAIL, MICROSOFT® ENTOURAGE®, MICROSOFT® OUTLOOK®, MOZILLA® THUNDERBIRD®, and the like.

Furthermore, one or more computer-readable storage media may be utilized in implementing embodiments consistent with the present invention. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., non-transitory. Examples include Random Access Memory (RAM), Read-Only Memory (ROM), volatile memory, nonvolatile memory, hard drives, Compact Disc (CD) ROMs, Digital Video Disc (DVDs), flash drives, disks, and any other known physical storage media.

In light of the technical advancements provided by the disclosed method, the claimed steps, as discussed above, are not routine, conventional, or not well-known aspects in the art, as the claimed steps provide the aforesaid solutions to the technical problems existing in the conventional technologies. Further, the claimed steps clearly bring an improvement in the functioning of the system itself, as the claimed steps provide a technical solution to a technical problem.

The terms “an embodiment”, “embodiment”, “embodiments”, “the embodiment”, “the embodiments”, “one or more embodiments”, “some embodiments”, and “one embodiment” mean “one or more (but not all) embodiments of the invention(s)” unless expressly specified otherwise.

The terms “including”, “comprising”, “having” and variations thereof mean “including but not limited to”, unless expressly specified otherwise.

The enumerated listing of items does not imply that any or all the items are mutually exclusive, unless expressly specified otherwise. The terms “a”, “an” and “the” mean “one or more”, unless expressly specified otherwise.

A description of an embodiment with several components in communication with each other does not imply that all such components are required. On the contrary, a variety of optional components are described to illustrate the wide variety of possible embodiments of the invention.

When a single device or article is described herein, it will be clear that more than one device/article (whether they cooperate) may be used in place of a single device/article. Similarly, where more than one device/article is described herein (whether they cooperate), it will be clear that a single device/article may be used in place of the more than one device/article or a different number of devices/articles may be used instead of the shown number of devices or programs. The functionality and/or features of a device may be alternatively embodied by one or more other devices which are not explicitly described as having such functionality/features. Thus, other embodiments of invention need not include the device itself.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limiting, of the scope of the invention, which is set forth in the following claims.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A verification and debugging tool for Register Transfer Level (RTL) code blocks, the verification and debugging tool comprising:
an input interface configured to receive RTL code in a Hardware Description Language (HDL);
an RTL parser configured to parse the RTL code and generate an abstract syntax tree;
a graph converter configured to convert the abstract syntax tree into an RTL directed graph, wherein the RTL directed graph comprises a plurality of code blocks represented as nodes and each node corresponding to a functional block of the RTL code;
a replacement module configured to:
determine one or more unique global names for signals across an overall hierarchy of RTL blocks, and
replace local signal names in lower-level RTL blocks with corresponding global names from higher-level RTL blocks without displaying full hierarchy preceding global name; and
a visual display configured to display the RTL directed graph with directional links indicating signal flow, and further configured to provide interactive mechanisms to display at least one of:
the full hierarchy of RTL blocks preceding the global name, and
the replaced local name associated with the global name.

2. The verification and debugging tool of claim 1, wherein the overall hierarchy of RTL blocks is flattened by driving global names from higher-level RTL blocks down through lower-level RTL blocks.

3. The verification and debugging tool of claim 1, wherein the replacement module is configured to verify uniqueness in name of each signal name across the overall hierarchy of RTL blocks.

4. The verification and debugging tool of claim 1, wherein the replacement module is configured to maintain the full hierarchy of RTL blocks preceding the global name while visually displaying only the global name in the local signal names.

5. The verification and debugging tool of claim 1, wherein the visual display is configured to provide an interactive mechanism, wherein the interactive mechanism comprises at least one of hovering over or clicking a sensitive region around a displayed global name to display the full hierarchy or the replaced local name.

6. The verification and debugging tool of claim 1, wherein each node of the RTL directed graph corresponds to an RTL code block and is represented using a node list comprising information of one or more signals defined in the corresponding RTL code block.

7. The verification and debugging tool of claim 1, wherein directional linkages in the RTL directed graph indicates the signal flow both upstream and downstream to visualize interconnections between code blocks.

8. The verification and debugging tool of claim 1, wherein signals of RTL code blocks are represented in the RTL directed graph to provide a global visual view of all code blocks and corresponding interrelations.

9. The verification and debugging tool of claim 1, wherein the visual display is configured to display a global visual view of the RTL directed graph for analysis of multiple code blocks concurrently.

10. The verification and debugging tool of claim 1, further comprises:
a memory configured to:
store node block structures and signal mappings, including replaced local names and corresponding global names; and
store mappings between the local signal names in lower-level RTL blocks and corresponding global names from higher-level RTL blocks to support interactive display of replaced local names.

11. The verification and debugging tool of claim 1, wherein the visual display is configured to selectively reveal the full hierarchy of RTL blocks preceding the global name upon user interaction while preserving readability when not revealed.

12. The verification and debugging tool of claim 1, wherein the graph converter is further configured to provide one or more customizable display options for the RTL directed graph.

13. The verification and debugging tool of claim 12, wherein the one or more customizable display options comprises at least one of color coding for different types of signals, adjustable node sizes, and selectable layers of data flow representation.

14. The verification and debugging tool of claim 1, wherein the visual display is configured to support zoom functionality for viewing details of individual code blocks or nodes.

15. The verification and debugging tool of claim 14, wherein the zoom functionality allows a user to focus on specific areas of the RTL directed graph while preserving ability to return to an overall view.

16. The verification and debugging tool of claim 1, wherein the RTL directed graph is configured to display at least one of control flow and data flow, wherein the at least one of the control flow and the data flow is displayed in a visually distinguishable manner.

17. The verification and debugging tool of claim 1, wherein the visual display enables a switch between visualization of signals in a waveform window and visualization of the corresponding generating code block.

18. A method of replacing of names of local signal with the global name in Register Transfer Language (RTL) code blocks, the method comprising:
receiving RTL code in a Hardware Description Language (HDL);
parsing the RTL code, and generating an abstract syntax tree representing the syntactic structure of the RTL code;
converting the abstract syntax tree into an RTL directed graph, wherein the RTL directed graph comprises a plurality of RTL code blocks represented as nodes and each node corresponding to a functional block of the RTL code;
determining one or more unique global names for signals across an overall hierarchy of RTL blocks;
replacing local signal names in lower-level RTL blocks with corresponding global names from higher-level RTL blocks without displaying full hierarchy preceding global name; and
displaying the RTL directed graph with directional links indicating signal flow, and providing interactive mechanisms to display at least one of:
the full hierarchy of RTL blocks preceding the global name, and
the replaced local name associated with the global name.

19. A non-transitory computer readable medium including instructions stored thereon that when processed by at least one processor, cause a verification and debugging tool to perform operations comprising:
receiving RTL code in a Hardware Description Language (HDL);
parsing the RTL code, and generating an abstract syntax tree representing the syntactic structure of the RTL code;
converting the abstract syntax tree into an RTL directed graph, wherein the RTL directed graph comprises a plurality of RTL code blocks represented as nodes and each node corresponding to a functional block of the RTL code;
determining one or more unique global names for signals across an overall hierarchy of RTL blocks;
replacing local signal names in lower-level RTL blocks with corresponding global names from higher-level RTL blocks without displaying full hierarchy preceding global name; and
displaying the RTL directed graph with directional links indicating signal flow, and providing interactive mechanisms to display at least one of:
the full hierarchy of RTL blocks preceding the global name, and
the replaced local name associated with the global name.
